(19) United States
(12) Patent Application Publication
(10) Pub. No.: US 2020/0413565 A1
(43) Pub. Date: Dec. 31, 2020

(54) HEAT CONDUCTING STRUCTURE, MANUFACTURING METHOD THEREOF, AND MOBILE DEVICE

(71) Applicant: CTRON ADVANCED MATERIAL CO., LTD., Xinxiang City (CN)

(72) Inventor: Yi-Hau SHIAU, Taichung City (TW)

(21) Appl. No.: 16/581,120

(22) Filed: Sep. 24, 2019

(30) Foreign Application Priority Data
Jun. 28, 2019 (TW) 108123019

(51) Int. Cl. H05K 7/20; F28D 15/04

(52) U.S. Cl. CPC H05K 7/20336; H05K 7/20445; H04M 1/0202; H05K 7/20318; F28D 15/046; H05K 7/20309

(57) ABSTRACT

A heat conducting structure comprises a heat conducting unit, a first heat conducting layer, a metal microstructure, a second heat conducting layer and a working fluid. The heat conducting unit forms a closed chamber having opposite bottom surface and top surface. Opposite ends of the heat conducting unit are functioned as a heat source end and a cooling end, respectively. The first heat conducting layer is disposed on the bottom surface and/or the top surface of the closed chamber. The metal microstructure is disposed on the first heat conducting layer. The second heat conducting layer is disposed at one side of the metal microstructure. The total thickness of the first and second heat conducting layers adjacent to the heat source end is greater than the total thickness thereof away from the heat source end. A manufacturing method of the heat conducting structure and a mobile device are disclosed.

### CROSS REFERENCE TO RELATED APPLICATIONS

This Non-provisional application claims priority under 35 U.S.C. § 119(a) on Patent Application No(s). 108123019 filed in Taiwan, Republic of China on Jun. 28, 2019, the entire contents of which are hereby incorporated by reference.

### BACKGROUND

### Technology Field

The present disclosure relates to a heat conducting structure, a manufacturing method thereof, and a mobile device having the heat conducting structure.

### Description of Related Art

With the progress of technology, the design and development of mobile devices are mostly focused on the thinning and high performance of the products. In the case of high-speed calculation and thinning, the computing chip (such as CPU) inside the mobile device must also provide high-efficiency execution speed, and definitely generate extremely high heat (even over 100° C.). If the heat is not properly dissipated to the outside, it may cause permanent damage to the component or the mobile device.

In order to avoid overheating of the device, the conventional art is generally to provide a heat dissipation structure to dissipate the heat energy generated by the mobile device by way of conduction, convection and/or radiation. In addition, as the mobile device becomes thinner and lighter, the space inside the mobile device for installing various electronic components is also narrowed. Of course, the configured heat dissipation structure must also conform to the design of the narrowed space.

Therefore, it is an important subject to provide a heat conducting structure suitable for the high-power component or device, thereby satisfying the heat dissipation requirement for the thin and light mobile device.

### SUMMARY

An objective of the disclosure is to provide a heat conducting structure, a manufacturing method thereof, and a mobile device containing the heat conducting structure. The heat conducting structure of this disclosure has higher heat conducting efficiency, so that the heat energy generated by the heat source can be rapidly conducted to the outside, and the heat conducting structure can satisfy the heat dissipation requirement for the thin and light mobile device.

To achieve the above objective, the present disclosure provides a heat conducting structure, which comprises a heat conducting unit, a first heat conducting layer, a metal microstructure, a second heat conducting layer, and a working fluid. The heat conducting unit forms a closed chamber, which has a bottom surface and a top surface. The bottom surface and the top surface are opposite to each other. Two opposite ends of the heat conducting unit are functioned as a heat source end and a cooling end, respectively. The first heat conducting layer is disposed on the bottom surface and/or the top surface of the closed chamber. The metal microstructure is disposed on the first heat conducting layer, and the first heat conducting layer is located between the metal microstructure and the bottom surface and/or the top surface. The second heat conducting layer is disposed at one side of the metal microstructure away from the first heat conducting layer. The working fluid is disposed in the closed chamber of the heat conducting unit. A total thickness of the first heat conducting layer and the second heat conducting layer adjacent to the heat source end is greater than a total thickness of the first heat conducting layer and the second heat conducting layer away from the heat source end.

In one embodiment, the first heat conducting layer or the second conducting layer covers at least a part surface of the microstructure.

In one embodiment, the first heat conducting layer, the metal microstructure and the second heat conducting layer form a stacking structure. The stacking structure is divided into at least two sections along a long-axis direction, and the at least two sections comprises a first section and a second section. The materials of the first heat conducting layer and the second heat conducting layer in the first section are at least partially different from the material of the first heat conducting layer and the second heat conducting layer in the second section.

In one embodiment, the metal microstructure comprises a metal mesh, a metal powder, or a metal particle, or any combination thereof.

In one embodiment, a material of the first heat conducting layer or the second heat conducting layer comprises graphene, graphite, carbon nanotube, aluminum oxide, zinc oxide, titanium oxide, or boron nitride, or any combination thereof.

In one embodiment, the heat conducting structure further comprises a third heat conducting layer disposed at one side of the second heat conducting layer away from the metal microstructure.

In one embodiment, the total thickness of the first heat conducting layer, the second heat conducting layer and the third heat conducting layer adjacent to the heat source end is greater than the total thickness of the first heat conducting layer, the second heat conducting layer and the third heat conducting layer away from the heat source end.

In one embodiment, the first heat conducting layer, the metal microstructure, the second heat conducting layer and the third heat conducting layer form a stacking structure. The stacking structure is divided into at least two sections along a long-axis direction, and the at least two sections comprises a first section and a second section. The materials of the first heat conducting layer, the second heat conducting layer and the third heat conducting layer in the first section are at least partially different from the material of the first heat conducting layer, the second heat conducting layer and the third heat conducting layer in the second section.

In one embodiment, the third heat conducting layer comprises a plurality of nanotubes, and axial directions of the nanotubes are perpendicular to a surface of the second heat conducting layer.

In one embodiment, the heat conducting structure further comprises a fourth heat conducting layer disposed on a part of an inner surface of the closed chamber configured without the first heat conducting layer, the metal microstructure and the second heat conducting layer.

In one embodiment, the heat conducting structure further comprises a carbon material added into the working fluid.

To achieve the above objective, the present disclosure also provides a mobile device comprising a heat source and the above-mentioned heat conducting structure. One end of the heat conducting structure contacts with the heat source.

To achieve the above objective, the present disclosure further provides a manufacturing method of a heat conducting structure. The manufacturing method comprises the steps of: forming a first heat conducting layer on a first substrate and/or a second substrate; forming a metal microstructure on the first substrate and/or the second substrate, wherein the first heat conducting layer is located between the metal microstructure and the first substrate and/or the second substrate; forming a second heat conducting layer at one side of the metal microstructure away from the first heat conducting layer, wherein a total thickness of the first heat conducting layer and the second heat conducting layer adjacent to a heat source end of the heat conducting structure is greater than a total thickness of the first heat conducting layer and the second heat conducting layer away from the heat source end; assembling the first substrate and the second substrate to form a heat conducting unit, wherein the heat conducting unit forms a closed chamber; and injecting a working fluid into the closed chamber through a recess of the heat conducting unit.

To achieve the above objective, the present disclosure further provides another manufacturing method of a heat conducting structure. The manufacturing method comprises the steps of: forming a first heat conducting layer on a metal microstructure; forming a second heat conducting layer at one side of the metal microstructure away from the first heat conducting layer, wherein a total thickness of the first heat conducting layer and the second heat conducting layer adjacent to a heat source end of the heat conducting structure is greater than a total thickness of the first heat conducting layer and the second heat conducting layer away from the heat source end; disposing the metal microstructure formed with the first heat conducting layer and the second heat conducting layer on a first substrate and/or a second substrate, wherein the first heat conducting layer is located between the metal microstructure and the first substrate and/or the second substrate; assembling the first substrate and the second substrate to form a heat conducting unit, wherein the heat conducting unit forms a closed chamber; and injecting a working fluid into the closed chamber through a recess of the heat conducting unit.

In one embodiment, before the step of assembling the first substrate and the second substrate, the manufacturing method further comprises a step of: forming a third heat conducting layer at one side of the second heat conducting layer away from the metal microstructure, wherein a total thickness of the first heat conducting layer, the second heat conducting layer and the third heat conducting layer adjacent to the heat source end is greater than a total thickness of the first heat conducting layer, the second heat conducting layer and the third heat conducting layer away from the heat source end.

In one embodiment, before the step of assembling the first substrate and the second substrate, the manufacturing method further comprises a step of: forming a fourth heat conducting layer on a part of an inner surface of the closed chamber configured without the first heat conducting layer, the metal microstructure, the second heat conducting layer, and the third heat conducting layer.

In one embodiment, before the step of assembling the first substrate and the second substrate, the manufacturing method further comprises a step of: forming a fourth heat conducting layer on a part of an inner surface of the closed chamber configured without the first heat conducting layer, the metal microstructure and the second heat conducting layer.

As mentioned above, in the heat conducting structure, the manufacturing method thereof, and the mobile device of this disclosure, the first heat conducting layer and the second heat conducting layer are disposed at two sides of the metal microstructure inside the heat conducting structure. This configuration can increase the hydrophilicity of the metal microstructure so as to increase the reflux rate of the liquid working fluid at the metal microstructure, thereby accelerating the circulation efficiency of the working fluid, and improving the temperature uniform effect and heat conduction effect of the heat conducting structure. In addition, since the total thickness of the first heat conducting layer and the second heat conducting layer adjacent to the heat source end is greater than the total thickness of the first heat conducting layer and the second heat conducting layer away from the heat source end, the heat conducting structure can have a longer lifetime and better product reliability. As a result, the heat conducting structure of the present disclosure not only can satisfy the heat dissipation requirement of the thin and light mobile device, but also can rapidly dissipate the heat energy generated by the heat source to the outside, thereby having longer lifetime and better product reliability.

In some embodiments, the heat conducting structure of this disclosure further comprises a third heat conducting layer, which is disposed at one side of the second heat conducting layer away from the metal microstructure. The configuration of the third heat conducting layer can increase the heat conduction efficiency of the heat conducting structure, increase the coverage and hydrophilicity, and improve the protection of the metal microstructure so as to prevent corrosion or oxidation.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1A is a schematic diagram showing a heat conducting structure according to an embodiment of this disclosure;

FIG. 1B is a sectional view of the heat conducting structure of FIG. 1A along the line A-A;

FIG. 1C is a sectional view of the heat conducting structure of FIG. 1A along the line X-X;

FIGS. 1D and 1E are schematic diagrams showing different embodiments of the heat conducting structure of FIG. 1B, wherein the first heat conducting layer and the second heat conducting layer are disposed at two sides of the metal microstructure;

FIG. 1F is a sectional view of the heat conducting structure according to another embodiment of this disclosure;

FIG. 2 is a sectional view of the heat conducting structure according to another embodiment of this disclosure;

FIGS. 3A, 3B and 3C are different sectional views of the heat conducting structure according to another embodiment of this disclosure;

FIG. 4 is a schematic diagram showing a mobile device according to an embodiment of this disclosure;

FIGS. 5A and 5B are different flow charts of the manufacturing method of the heat conducting structure of this disclosure;

FIGS. 6A to 6E are schematic diagrams showing the manufacturing procedure of the heat conducting structure according to an embodiment of this disclosure; and

FIGS. 7A and 7B are schematic diagrams showing a part of another manufacturing procedure of the heat conducting structure according to an embodiment of this disclosure.

### DETAILED DESCRIPTION OF THE DISCLOSURE

The present disclosure will be apparent from the following detailed description, which proceeds with reference to the accompanying drawings, wherein the same references relate to the same elements.

The heat conducting structure of the present disclosure can have higher heat conducting efficiency, thereby rapidly dissipating the heat energy generated by the heat source and satisfy the heat dissipation requirement of the thin and light mobile device. The heat conducting structure can be disposed inside the mobile device, and one end thereof contacts the heat source to conduct the heat energy generated by the heat source to the other end thereof through the heat conducting structure, thereby preventing the crash or burn of the mobile device caused by the high temperature of the heat source. In some embodiments, the heat source can be, for example but not limited to, a central processing unit (CPU), a memory chip (card), a display chip (card), a panel, or a power component in the mobile device, or any of other components, units or assemblies that can generate high temperature. In addition, the aforementioned mobile device may be, for example but not limited to, a mobile phone, a notebook computer, a tablet computer, a television, or a display related mobile electronic device, or a mobile device in any of other fields.

In addition, the heat conducting structure of the present disclosure may be a vapor chamber or a heat pipe. The heat pipe is a circular pipe having a one-dimensional and linear heat conduction mode. The vapor chamber is a two-dimensional and surface heat conduction mode, which is a high-performance method capable of rapidly transmitting a local heat source to the other side of the vapor chamber. The design of the vapor chamber can solve the more critical heat dissipation problem and have higher heat dissipation efficiency. The heat conducting structure of the following embodiments is exemplified by a flat vapor chamber, but it can also be a heat pipe. In addition, in order to explain the internal structure of the heat conducting structure, the length and shape shown in the following drawings are only for illustrations. In practice, the heat conducting structure may be bent in the horizontal direction and/or the vertical direction, and the bending manner may be selected based on the situations of the heat source and internal space of the mobile device.

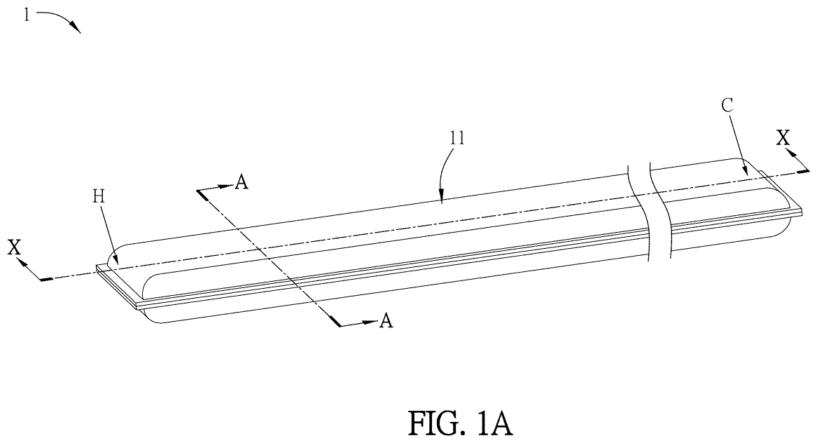

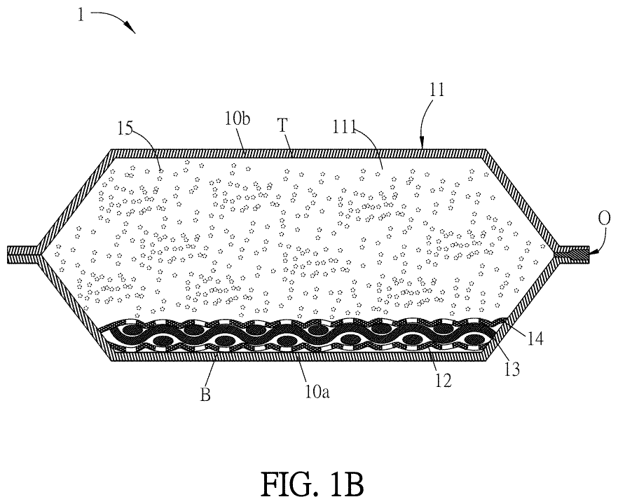

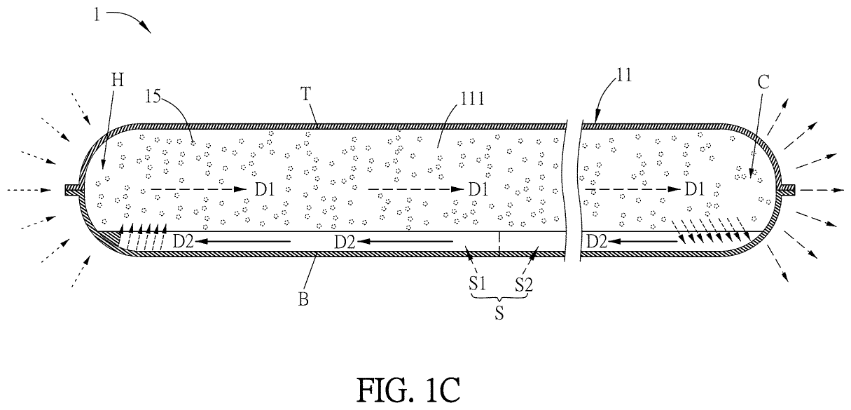

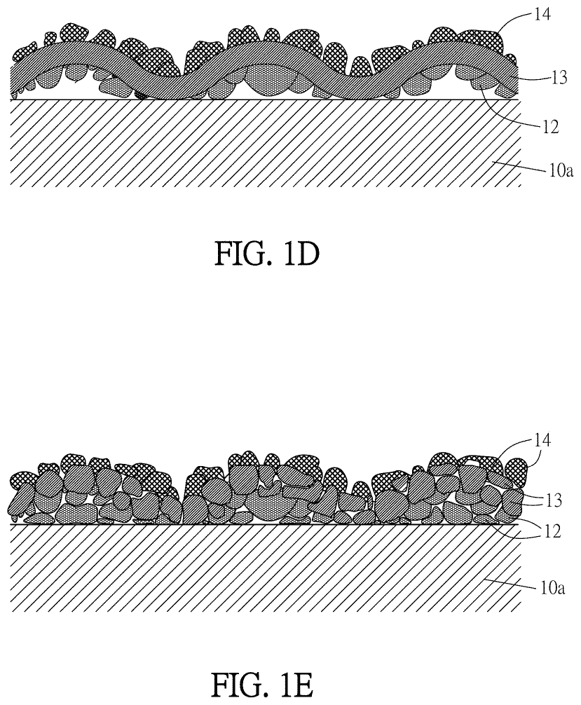

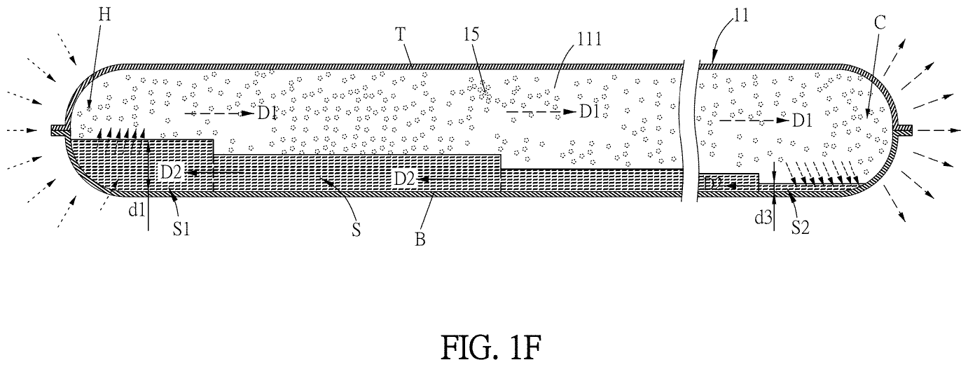

FIG. 1A is a schematic diagram showing a heat conducting structure according to an embodiment of this disclosure, FIG. 1B is a sectional view of the heat conducting structure of FIG. 1A along the line A-A, and FIG. 1C is a sectional view of the heat conducting structure of FIG. 1A along the line X-X. Herein, the direction of the line X-X is the long-axis direction of the heat conducting structure (or the heat conducting unit).

As shown in FIGS. 1A to 1C, the heat conducting structure 1 comprises a heat conducting unit 11, a first heat conducting layer 12, a metal microstructure 13, at least one second heat conducting layer 14, and a working fluid 15.

The heat conducting unit 11 forms a closed chamber 111, and the closed chamber 111 has a bottom surface B and a top surface T, which are opposite to each other. In some embodiments, the heat conducting structure is made of a thin plate with a thickness less than 0.4 mm (e.g. 0.35 mm) for fitting the heat conducting and heat dissipation requirements of a thin mobile device. In this embodiment, two opposite ends of the heat conducting unit 11 are functioned as a heat source end H (or heat source side) and a cooling end C (or cooling side), respectively. As shown in FIGS. 1A and 1C, the heat source end H is one end of the heat conducting unit 11 adjacent to the heat source, and the cooling end C is one end of the heat conducting unit 11 away from the heat source. In addition, the heated part of the closed chamber 111 of the heat conducting unit 11 is also named as an evaporating area, and the other side of the closed chamber 111 opposite to the evaporating area is named as a condensing area. The working fluid 15 can absorb the heat energy at the evaporating area and then evaporated to expand and fill the entire closed chamber 111. Afterwards, the working fluid 15 can release the heat energy at the condensing area and then return to the liquid state, and the liquid working fluid 15 flows to the evaporating area again. The cycling of the working fluid 15 can rapidly transfer the heat energy and balance the temperature.

The heat conducting unit 11 has a structure capable of withstanding the difference of the internal pressure and the external pressure, and the material thereof is a dielectric material that can conduct heat in and out. The heat conducting unit 11 may be manufactured by welding a plurality of metal plates, or be a single integrated unit. In this embodiment, the heat conducting unit 11 is formed by assembling two recessed metal plates (such as the first substrate 10a and the second substrate 10b of FIG. 1B) by, for example, soldering. The preferred material of the heat conducting unit 11 is a metal such as, for example but not limited to, a highly thermal conductive metal material including copper, aluminum, iron, silver, gold, and the like. In this embodiment, the heat conducting unit 11 is made of copper.

The first heat conducting layer 12 is disposed on the bottom surface B and/or the top surface T of the closed chamber 111. In this embodiment, the first heat conducting layer 12 is disposed on the bottom surface B of the closed chamber 111. In other embodiments, the first heat conducting layer 12 is disposed on the top surface T of the closed chamber 111. In other embodiments, the first heat conducting layer 12 is disposed on the bottom surface B and the top surface T of the closed chamber 111.

The metal microstructure 13 is disposed on the first heat conducting layer 12, so that the first heat conducting layer 12 is located between the metal microstructure 13 and the bottom surface B and/or the top surface T. In this embodiment, the metal microstructure 13 is disposed on the bottom surface B of the first heat conducting layer 12, and the first heat conducting layer 12 is located between the metal microstructure 13 and the bottom surface B. The metal microstructure 13 can be a wick structure in the profile of metal meshes, metal powders, metal particles (including metal nanoparticles), metal pillars (e.g. cylinders, pyramids, or square cylinders), or any combination thereof, or a non-metal material structure coated with metal material, or any profile that can increase the surface area of the heat conducting layers. The material of the metal microstructure 13 can be, for example but not limited to, a highly thermal conductive metal material including copper, aluminum, iron, silver, gold, and the like, or any of other suitable materials. In practice, the wick structure (metal microstructure 13) can have different designs, and the four common designs include the groove type, mesh type (woven), fiber type and sintered type. Since the inner side of the heat conducting unit 11 is configured with the metal microstructure 13, the heat energy carried by the gaseous working fluid 15 can be dissipated out of the heat conducting unit 11 at the condensing area (cooling end C). Then, the gaseous working fluid 15 can be condensed to obtain the liquid working fluid 15, which can flow toward the evaporating area (heat source end H) through the metal microstructure 13 on the bottom surface B of the heat conducting unit 11 (flow direction D2 of FIG. 1C). Accordingly, the working fluid 15 can be continuously circulated inside the heat conducting unit 11. In this embodiment, the metal microstructure 13 is exemplified by a copper mesh.

At least one second heat conducting layer 14 is disposed on a side of the metal microstructure 13 away from the first heat conducting layer 12. As shown in FIG. 1B, a single-layer second heat conducting layer 14 is disposed on the metal microstructure 13 such that the metal microstructure 13 is located between the second heat conducting layer 14 and the first heat conducting layer 12 (“S” shown in FIG. 1C represents a stacked structure of the second heat conducting layer 14, the metal microstructure 13, and the first heat conducting layer 12). The above-mentioned first heat conducting layer 12 and second heat conducting layer 14 may include a material having a high thermal conductivity, which may be an organic material or an inorganic material. The organic material may include a carbon material such as, for example but not limited to, graphite, graphene, carbon nanotubes, carbon spheres, carbon wires, and the like, and the inorganic material may include, for example but not limited to, a high thermal conductive metal or a combination thereof.

In some embodiments, the first heat conducting layer 12 or the second heat conducting layer 14 covers at least a part surface of the metal microstructure 13. In some embodiments, the covering rate of the first heat conducting layer 12 or the second heat conducting layer 14 on metal microstructure 13 is greater than or equal to 0.001% and is less than or equal to 100% (0.001%≤covering rate≤100%). Herein, the 100% covering rate means that the first heat conducting layer 12 or the second heat conducting layer 14 covers all of the surface of the metal microstructure 13. In some embodiments, the covering rate of the first heat conducting layer 12 or the second heat conducting layer 14 on metal microstructure 13 is greater than or equal to 5% and is less than or equal to 100% (5%≤covering rate≤100%). For example, the covering rate can be 7%, 10%, 12%, 15%, 20%, 25%, 30%, . . . , or 90%. In some embodiments, the covering rate of the first heat conducting layer 12 or the second heat conducting layer 14 on metal microstructure 13 is greater than or equal to 0.001% and is less than or equal to 5% (0.001%≤covering rate≤5%). For example, the covering rate can be 0.005%, 0.01%, 0.02%, 0.5%, 1%, . . . , or 3%, and this disclosure is not limited thereto. In addition, the features of the first heat conducting layer 12 or the second heat conducting layer 14, which covers at least a part surface of the metal microstructure 13, and the covering rate thereof can be applied to other embodiments of this disclosure.

In some embodiments, the material of the first heat conducting layer 12 and/or the second heat conducting layer 14 comprises, for example but not limited to, graphene, graphite, multi-walled carbon nanotube, aluminum oxide, zinc oxide, titanium oxide, or boron nitride, or any combination thereof, or any of other high thermal conductive organic or inorganic materials. The above-mentioned organic material comprises OD (dimension), 1D, 2D or 3D materials. The OD material can be, for example but not limited to, graphene quantum dots, the 1D material can be, for example but not limited to, carbon nanotubes, the 2D material can be, for example but not limited to, graphene microchips or MoS₂, and the 3D material can be, for example but not limited to, graphite. Preferably, the material of the first heat conducting layer 12 and/or the second heat conducting layer 14 is graphene, carbon nanotube, or a combination thereof. In this embodiment, the materials of the first heat conducting layer 12 and the second heat conducting layer 14 are both graphene. In some embodiments, the heat conducting layer 12 and the second heat conducting layer 14 can cover a part surface or the entire surface of the metal microstructure 13. In some embodiments, the first heat conducting layer 12 and the second heat conducting layer 14 are made of graphene thermal film (GTF).

Since the graphene material (the first heat conducting layer 12 and the second heat conducting layer 14) has a good heat conductivity in the xy plane, the heat conducting efficiency of the metal microstructure 13 can be improved. In addition, the graphene material (the first heat conducting layer 12 and the second heat conducting layer 14) can also increase the hydrophilic property of the metal microstructure 13 (e.g. copper mesh) and protect the metal microstructure 13 from oxidation and corrosion. Herein, the good hydrophilic property represents a smaller contact angle, so that the working fluid 15 in the closed chamber 111, such as water and water vapor, can be more easily attached to the surface of the graphene continuously. Accordingly, the water is more easily evaporated, the water vapor is more easily condensed, and the circulation reflux speed can be faster, thereby transferring heat more quickly. It should be noted that in this embodiment, the second heat conducting layer 14 is disposed at the side of the metal microstructure 13 away from the first heat conducting layer 12. In different embodiments, multiple second heat conducting layers 14 (e.g. a multilayer graphene film) may be disposed on the metal microstructure 13, and this disclosure is not limited thereto. In addition, in other embodiments, the materials of the first heat conducting layer 12 and the second heat conducting layer 14 may be different.

FIGS. 1D and 1E are schematic diagrams showing different embodiments of the heat conducting structure of FIG. 1B, wherein the first heat conducting layer and the second heat conducting layer are disposed at two sides of the metal microstructure.

For example, the metal microstructure 13 of FIG. 1D is a copper mesh, and the first heat conducting layer 12 and the second heat conducting layer 14 are made of graphene. As shown in FIG. 1D, a part of the metal microstructure 13 (copper mesh) is disposed on (connected to) the surface of the first substrate 10a, and a plurality of graphene materials (configured to form the first heat conducting layer 12) are provided to cover a part of the lower surface of the metal microstructure 13 and located between the metal microstructure 13 and the first substrate 10a. The additional graphene materials (configured to form the second heat conducting layer 14) are provided to cover a part of the upper surface of the metal microstructure 13, so that the metal microstructure 13 is located between the first heat conducting layer 12 and the second heat conducting layer 14.

Alternatively, the metal microstructure 13 of FIG. 1E is copper powder, and the first heat conducting layer 12 and the second heat conducting layer 14 are made of graphene. As shown in FIG. 1E, a part of the metal microstructure 13 (copper powder) is disposed on (connected to) the surface of the first substrate 10a, and the graphene material (configured to form the first heat conducting layer 12) is provided to cover a part of the lower surface of the metal microstructure 13 and located between the metal microstructure 13 and the first substrate 10a. The additional graphene material (configured to form the second heat conducting layer 14) is provided to cover a part of the upper surface of the metal microstructure 13, so that the metal microstructure 13 is located between the first heat conducting layer 12 and the second heat conducting layer 14.

Referring to FIGS. 1B and 1C, the working fluid 15 is filled and disposed inside the closed chamber 111 of the heat conducting unit 11. Since the heat source end H of the heat conducting structure 1 is in contact with the heat source, the heat energy can be conducted to the heat source end H of the heat conducting unit 11 (the arrow directing toward the heat source end H shown in FIG. 1C indicates that the heat energy is transferred to the heat source end H), so that the heat source end H can have a higher temperature for vaporizing the working fluid 15 around the heat source end H. The working fluid 15 may be selected from a refrigerant or other heat transfer fluid such as, for example but not limited to, Freon, ammonia, acetone, methanol, ethylene glycol, propylene glycol, dimethyl sulfoxide (DMSO), or water. The selection of the working fluid 15 can be determined according to the type or model of the heat source of the mobile device, as long as the selected working fluid 15 can be vaporized into a gaseous state by the heat source temperature in the heat source end H, and then condensed and refluxed in the cooling end C. In this embodiment, the working fluid 15 is exemplified by water.

To be noted, when the refrigerant is selected as the working fluid 15, and before the refrigerant is injected into the heat conducting unit 11, the closed chamber 111 must be evacuated to prevent the presence of impurity gases (e.g. air) other than the working fluid 15 inside the heat conducting unit 11. Without this evacuation step, the impurity (e.g. air) becomes the non-condensing gas since it does not participate in the vaporization-condensation cycle. The non-condensing gas may increase the vaporization temperature, and will occupy a certain volume of space in the chamber of the heat conducting unit 11 so as to affecting the heat conducting efficiency of the heat conducting structure 1 as the heat conducting structure 1 is operated. In addition, the heat conducting structure 1 can be connected to the heat source through, for example but not limited to, a thermal conductive paste or a thermal grease, and the heat source of the mobile device can be connected to the heat source end H of the heat conducting structure 1 by the heat conductive paste or the thermal grease to conduct the heat energy of the heat source to the heat source end H of the heat conducting structure 1. In some embodiments, the heat conductive paste or thermal grease may comprise a hardener containing a thermal conductive polyxanthene composition, a thermal conductive filler, a polyoxyxene resin, and an organic peroxide based compound. In some embodiments, the material of the thermal conductive paste or thermal grease may also include an acrylic type adhesive.

When the heat conducting structure 1 contacts the heat source, the temperature of the heat source end H of the heat conducting unit 11 is increased, so that the working fluid 15 around the heat source end H can be evaporated. Then, the gaseous working fluid 15 can move along a flow path of the closed chamber 111 toward the cooling end C (i.e., along the flow direction D1) to carry away the heat energy generated by the heat source through the working fluid 15. After reaching the cooling end C, the heat energy of the working fluid 15 can be dissipated to the outside of the heat conducting unit 11 (the arrow directing away from the cooling end C indicates that the heat energy is dissipated from the cooling end C). Since the bottom surface B of the heat conducting unit 11 is configured with the metal microstructure 13, the condensed liquid working fluid 15 can return to the heat source end H (flow direction D2) along the metal microstructure 13. Accordingly, the working fluid 15 can continuously circulate and flow inside the heat conducting unit 11 for continuously carrying away the heat energy of the heat source and dissipating the heat energy through the cooling end C.

In this embodiment, the first heat conducting layer 12 and the second heat conducting layer 14 are made of graphene, and they are respectively disposed at two sides of the metal microstructure 13 to increase the hydrophilicity of the metal microstructure 13 (e.g. copper mesh), thereby increasing the flow rate of the gaseous working fluid leaving the metal microstructure 13 and the flow rate of the liquid working fluid 15 entering the metal microstructure 13. Therefore, the liquid working fluid 15 can quickly return to the heat source end H along the flow direction D2 to accelerate the circulation efficiency of the working fluid 15 and to improve the temperature uniform effect and heat conduction effect of the heat conducting structure 1. Compared with the conventional vapor chamber structure (which does not contain the first heat conducting layer 12 and the second heat conducting layer 14), the heat conducting structure 1 of this embodiment can quickly transfer the heat energy from the heat source end H to the cooling end C for reducing the temperature difference between the heat source end H and the cooling end C. To be noted, the smaller temperature difference represents a less resistance to heat conduction and a better heat conduction efficiency.

In some embodiments, in order to increase the heat conduction efficiency of the working fluid 15, the working fluid 15 can be added with the above-mentioned organic material (e.g. carbon, OD, 1D, 2D or 3D materials), inorganic material, or other materials with high thermal conductivity, or their combinations. In some embodiments, the working fluid 15 can be added with the carbon material, and the added amount of the carbon material can be greater than or equal to 0.0001% and less than or equal to 2% (0.0001% added amount 2%). In some embodiments, the added amount of the carbon material can be greater than or equal to 0.0001% and less than or equal to 1.5% (0.0001% added amount 1.5%). For example, the added amount can be 0.00015%, 0.005%, 0.01%, 0.03%, 0.1%, 0.5%, 1%, or 1.25%, and this disclosure is not limited thereto. The above-mentioned added amounts are for illustrations only and art not to limit the scope of this disclosure. As long as the added amount is between 0.0001% and 2%, the heat conduction efficiency of the working fluid can be improved, thereby improving the heat conduction efficiency of the heat conducting structure. To be noted, the above-mentioned feature of adding an organic material (e.g. carbon, OD, 1D, 2D, or 3D materials), an inorganic material, or other materials with high thermal conductivity to the working fluid 15 can also be applied to any of other embodiments of the present disclosure.

In some embodiments, the total thickness of the first heat conducting layer 12 and the second heat conducting layer 14 adjacent to the heat source end H is greater than the total thickness of the first heat conducting layer 12 and the second heat conducting layer 14 away from the heat source end H. Herein, the first heat conducting layer 12, the metal microstructure 12, and the second heat conducting layer 14 together form a stacked structure S. In some embodiments, the thickness of the stacked structure S is gradually decreased in stepwise. FIG. 1F is a sectional view of the heat conducting structure according to another embodiment of this disclosure. As shown in FIG. 1F, the metal microstructure 13 has a uniform thickness, and the total thickness of the first heat conducting layer 12 and the second heat conducting layer 14 is gradually decreased in stepwise along the line X-X (the long-axis direction of the heat conducting unit 11). Accordingly, in the stacked structure S, the first heat conducting layer 12 and the second heat conducting layer 14 closest to the heat source end H have the maximum total thickness, and the first heat conducting layer 12 and the second heat conducting layer 14 closest to the cooling end C have the minimum total thickness. To be noted, the total thickness can be the total thickness of one point or the average total thickness of an area, and this disclosure is not limited.

On the direction along the line X-X (the long-axis direction of the heat conducting unit 11), the above-mentioned stacked structure S can be divided into at least two sections, which at least includes a first section and a second section. Referring to FIG. 1F, the first section S1 is the part of the stacked structure S closest to the heat source end H, and the second section S2 is the part of the stacked structure S closest to the cooling end C. The first section S1 has a total thickness d1, and the second section S2 has a total thickness d3, and d1 is greater than d3 (d1>d3). In some embodiments, the total thickness of the first heat conducting layer 12 and the second heat conducting layer 14 in the first section S1 is greater than or equal to 1 nm and is less than or equal to 500 μm (1 nm≤d1≤500 μm). For example, the total thickness can be 10 nm, 500 nm, 1 μm, 20 μm, 350 μm, or 450 μm. In addition, the total thickness of the first heat conducting layer 12 and the second heat conducting layer 14 in the second section S2 is greater than or equal to 0 and is less than or equal to 1 nm (0≤d3≤1 nm). For example, the total thickness can be 0.05 nm, 0.08 nm, 0.1 nm, 0.5 nm, 0.75 nm, or 0.9 nm. This disclosure is not limited thereto. In some embodiments, the total thickness of the first heat conducting layer 12 and the second heat conducting layer 14 in the first section S1 is greater than or equal to 1 nm and is less than or equal to 1 μm (1 nm≤d1≤1 μm). For example, the total thickness can be 1.5 nm, 50 nm, 100 nm, 400 nm, 500 nm, 850 nm, or 900 nm. In addition, the total thickness of the first heat conducting layer 12 and the second heat conducting layer 14 in the second section S2 is greater than or equal to 0 and is less than or equal to 0.1 nm (0≤d3≤0.1 nm). For example, the total thickness can be 0.01 nm, 0.03 nm, 0.05 nm, 0.075 nm, 0.08 nm, 0.09 nm, or 0.095 nm. This disclosure is not limited thereto.

The reason for the embodiment of FIG. 1F to select the limitation in the total thickness is as follow. During the circulation including high temperature and low temperature of the working fluid 15, the material adhesion of the first heat conducting layer 12 and/or the second heat conducting layer 14 (e.g. graphene) can be weakened, thereby causing the deterioration of materials. Therefore, providing a thicker heat conducting layer (the first heat conducting layer 12 and the second heat conducting layer 14) in the first section, which is usually in the high temperature situation, can delay the deterioration of the material (graphene) and the damage of the adhesion, thereby increasing the lifetime and product reliability of the heat conducting structure.

In some embodiments, the thickness of the first heat conducting layer 12 may be fixed, but the thickness of the second heat conducting layer 14 may be varied. Otherwise, the thickness of the second heat conducting layer 14 may be fixed, but the thickness of the first heat conducting layer 12 may be varied. Alternatively, the thicknesses of the first heat conducting layer 12 and the second heat conducting layer 14 may be both varied as long as the total thickness of the first heat conducting layer 12 and the second heat conducting layer 14 adjacent to the heat source end H is greater than the total thickness of the first heat conducting layer 12 and the second heat conducting layer 14 away from the heat source end H. In addition, the embodiment of FIG. 1F is to change the total thickness of the first heat conducting layer 12 and the second heat conducting layer 14 in a stepwise manner such that the total thickness of the first heat conducting layer 12 and the second heat conducting layer 14 adjacent to the heat source end H is greater than the total thickness of the first heat conducting layer 12 and the second heat conducting layer 12 adjacent to the cooling end C. To be noted, this disclosure is not limited thereto. In different embodiments, the total thickness of the first heat conducting layer 12 and the second heat conducting layer 14 may be changed by an asymptotic change manner (i.e., gradually and smoothly changed from the thickest total thickness to the thinnest total thickness). The present disclosure is not limited as long as the total thickness of the first heat conducting layer 12 and the second heat conducting layer 14 adjacent to the heat source end H is greater than the total thickness of the first heat conducting layer 12 and the second heat conducting layer 14 away from the heat source end H. Moreover, in some embodiments, even if two different heat conducting structures both have the above-described limitation of total thickness, one of the heat conducting structure having a larger total thickness of the first heat conducting layer 12 and the second heat conducting layer 14 can have a better temperature uniform effect and a better protection to the materials. Herein, the better temperature uniform effect represents a smaller temperature difference between the heat source end H and the cooling end C, and the heat energy can be guided from the heat source end H to the cooling end C faster. To be noted, the feature of the above-mentioned limitation of total thickness can also be applicable to other embodiments of the disclosure.

Referring to FIG. 1F, the first section S1 is the part of the first heat conducting layer 12 and the second heat conducting layer 14 adjacent to the heat source end H having the total thickness d1, and the second section S2 is the part of the first heat conducting layer 12 and the second heat conducting layer 14 adjacent to the cooling end C having the total thickness d3 (d1>d3). Herein, the materials of the first heat conducting layer 12 and the second heat conducting layer 14 in the first section S1 are at least partially different from the materials of the first heat conducting layer 12 and the second heat conducting layer 14 in the second section S2. For example, in the stepwise stacked structure S of FIG. 1F, the materials of the first heat conducting layer 12 and the second heat conducting layer 14 in the first section S1 are graphene and graphene, respectively, but the materials of the first heat conducting layer 12 and the second heat conducting layer 14 in the second section S2 are graphene and carbon nanotubes, respectively. As long as the first heat conducting layer 12 and the second heat conducting layer 14 in any of the two sections of the stacked structure S comprise different materials, the above-mentioned condition that the materials of the first heat conducting layer 12 and the second heat conducting layer 14 in the first section S1 are at least partially different from the materials of the first heat conducting layer 12 and the second heat conducting layer 14 in the second section S2 can be satisfied. Furthermore, the feature that the first heat conducting layer 12 and the second heat conducting layer 14 in the at least two sections of the stacked structure have different materials can be also applicable to other embodiments of the present disclosure.

FIG. 2 is a sectional view of the heat conducting structure according to another embodiment of this disclosure.

The heat conducting structure 1a of FIG. 2 is most the same as the heat conducting structure 1 of FIG. 1B. Different from the heat conducting structure 1, the heat conducting structure 1a of FIG. 2 further comprises a third heat conducting layer 16, which is disposed at one side of the second heat conducting layer 14 away from the metal microstructure 13. In this embodiment, the third heat conducting layer 16 is disposed on the second heat conducting layer 14, so that the third heat conducting layer 16, the second heat conducting layer 14, the metal microstructure 13 and the first heat conducting layer 12 are stacked on the bottom surface B of the heat conducting unit 11 in sequence. The third heat conducting layer 16 may be made of the above-mentioned organic or inorganic material. In some embodiments, the material of the third heat conducting layer 16 may comprise multi-walled carbon nanotubes, aluminum oxide, zinc oxide, titanium oxide, graphene, graphite, boron nitride, or combinations thereof, or other materials having high thermal conductivity. The third heat conducting layer 16 of this embodiment is exemplified by a multi-walled carbon nanotube. In some embodiments, the third heat conducting layer 16 can include a plurality of nanotubes 161 (e.g. carbon nanotubes) having an axial direction perpendicular to a surface of the second heat conducting layer 14. Herein, the growth direction of the carbon nanotubes can be controlled by the process conditions such that the axial direction of the grown carbon nanotubes can be perpendicular to, for example, the planar direction of the graphene microchip (second heat conducting layer 14).

In some embodiments, the covering rate of the third heat conducting layer 16 on the second heat conducting layer 14 is greater than or equal to 0.001% and is less than or equal to 100% (0.001%≤covering rate≤100%). Herein, the 100% covering rate means that the third heat conducting layer 16 covers all of the surface of the second heat conducting layer 14. In some embodiments, the covering rate of the third heat conducting layer 16 on the second heat conducting layer 14 is greater than or equal to 5% and is less than or equal to 100% (5%≤covering rate≤100%). For example, the covering rate can be 7%, 10%, 12%, 15%, 20%, 25%, 30%, . . . , or 90%. In some embodiments, the covering rate of the third heat conducting layer 16 on the second heat conducting layer 14 is greater than or equal to 0.001% and is less than or equal to 5% (0.001%≤covering rate≤5%). For example, the covering rate can be 0.005%, 0.01%, 0.02%, 0.5%, 1%, . . . , or 3%, and this disclosure is not limited thereto. In addition, the features of the third heat conducting layer 16 covering at least a part surface of the second heat conducting layer 14, and the covering rate thereof can be applied to other embodiments of this disclosure.

In this embodiment, disposing the third heat conducting layer 16 (carbon nanotube) on the second heat conducting layer 14 can improve the flow rate of the working fluid 15 in to or out of the first heat conducting layer 12 and the second heat conducting layer 14, thereby increasing the heat conducting efficiency. Moreover, the configuration of the third heat conducting layer 16 (carbon nanotube) can also increase the covering rate of the second heat conducting layer 14 and the first heat conducting layer 12 (graphene layer). The high covering rate can increase the hydrophilic property of the second heat conducting layer 14 and the first heat conducting layer 12 (graphene layer) and protect the metal microstructure 13 from oxidation and corrosion. Herein, the good hydrophilic property represents a smaller contact angle, so that the working fluid 15 in the closed chamber 111, such as water and water vapor, can be more easily attached to the surface of the graphene continuously. Accordingly, the water is more easily evaporated, the water vapor is more easily condensed, and the circulation efficiency can be improved, thereby transferring heat more quickly.

In addition, the feature of configuring the third heat conducting layer 16 can also be applicable to other embodiments of this disclosure. For example, combining with the feature of stepwise or smoothly increased total thickness, the total thickness of the first heat conducting layer 12, the second heat conducting layer 14, and the third heat conducting layer 16 adjacent to the heat source end H is greater than the total thickness of the first heat conducting layer 12, the second heat conducting layer 14, and the third heat conducting layer 16 away from the heat source end H. In addition, combining with the feature of limitation of the total thickness, the total thickness of the first heat conducting layer 12, the second heat conducting layer 14, and the third heat conducting layer 16 in the first section S1 closest to the heat source end H is greater than or equal to 1 nm and is less than or equal to 500 and the total thickness of the first heat conducting layer 12, the second heat conducting layer 14, and the third heat conducting layer 16 in the second section S2 closest to the cooling end C is greater than or equal to 0 and is less than or equal to 1 nm. In addition, the materials of the first heat conducting layer 12, the second heat conducting layer 14, and the third heat conducting layer 16 in the first section S1 are at least partially different from the materials of the first heat conducting layer 12, the second heat conducting layer 14, and the third heat conducting layer 16 in the second section S2.

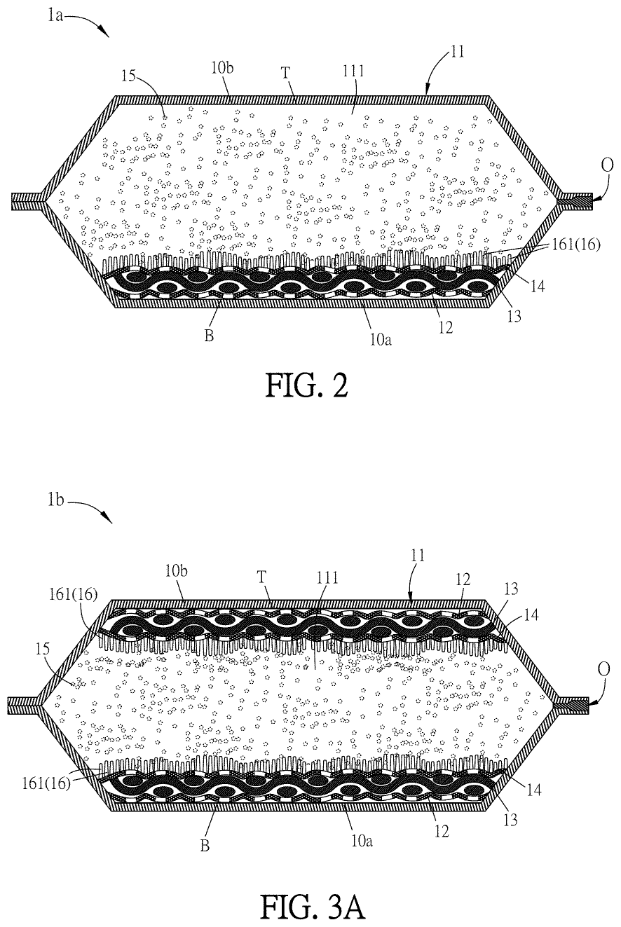

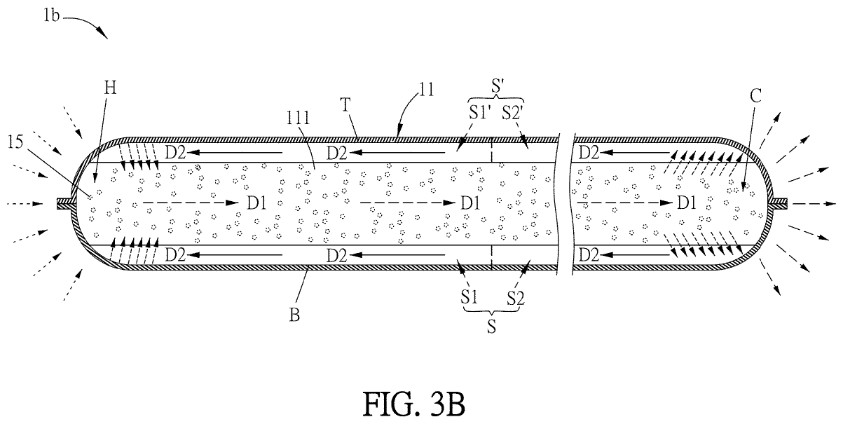

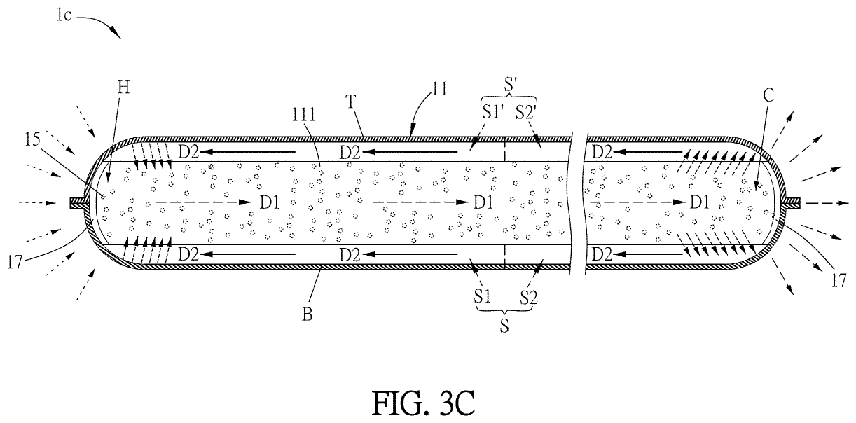

FIGS. 3A and 3B are different sectional views of the heat conducting structure according to another embodiment of this disclosure.

The heat conducting structure 1b of FIGS. 3A and 3B is most the same as the heat conducting structure 1a of FIG. 2. Different from the heat conducting structure 1a, the first heat conducting layer 12 of the heat conducting structure 1b is disposed on the bottom surface B and the top surface T of the closed chamber 111. As shown in FIG. 3A, the bottom surface B and the top surface T of the closed chamber 111 are configured with mirroring structures. In more detailed, the first heat conducting layer 12, the metal microstructure 13, the second heat conducting layer 14, and the third heat conducting layer 16 are disposed on the bottom surface B in sequence, and the first heat conducting layer 12, the metal microstructure 13, the second heat conducting layer 14, and the third heat conducting layer 16 are disposed on the top surface T in sequence. As shown in FIG. 3B, S and S′ represent two stacked structures of the third heat conducting layer 16, the second heat conducting layer 14, the metal microstructure 13, and the first heat conducting layer 12, and the stacked structures S and S′ are mirrored structures. Since the bottom surface B and the top surface T of the heat conducting unit 11 are respectively configured with the stacked structures S and S′, the condensed liquid working fluid 15 can be respectively returned to the heat source end H along the metal microstructures 13 on the bottom surface B and the top surface T (flow direction D2) to increase the reflux rate of the condensed liquid working fluid 15, thereby increasing the heat conducting efficiency. In addition, the features of the bottom surface B and the top surface T of the heat conducting structure both having the stacked structure may also be used in combine with the features of other embodiments of the present disclosure, such as stepped or smoothly changed total thickness, the limitation of the range of the total thickness, or partially different materials.

FIG. 3C is a sectional view of the heat conducting structure according to another embodiment of this disclosure.

The heat conducting structure 1c of FIG. 3C is most the same as the heat conducting structure 1b of FIG. 3B. Different from the heat conducting structure 1b, the heat conducting structure 1c of FIG. 3C further comprises a fourth heat conducting layer 17, which is disposed on a part of an inner surface of the closed chamber 111 configured without the stacked structures S and S′. In other words, the fourth heat conducting layer 17 is disposed on two opposite side walls of the closed chamber 111 and is not overlapped with the stacked structures S and S′. Of course, due to the possible manufacturing tolerance, the fourth heat conducting layer 17 may be partially overlapped with the stacked structures S and S′, and this disclosure is not limited. The material of the fourth heat conducting layer 17 can be the same as the material of the first heat conducting layer 12, the second heat conducting layer 14, or the third heat conducting layer 16. Preferably, the material of the fourth heat conducting layer 17 can be, for example, graphene or carbon nanotube. Accordingly, the covering rate of the heat conducting unit 11 can be increased, so that the material of the heat conducting unit 11 (e.g. copper) can have a better hydrophilic property, thereby increasing the heat conducting effect. Moreover, the fourth heat conducting layer 17 can further protect the heat conducting unit 11 from oxidation and corrosion.

In some embodiments, the fourth heat conducting layer 17 covers the part of the inner surface at two side walls of the closed chamber 111 configured without the stacked structures S and S′, and the covering rate thereof is greater than or equal to 0.01% and is less than or equal to 100% (0.01%≤covering rate≤100%). In some embodiments, the covering rate of the fourth heat conducting layer 17 can be greater than or equal to 0.02% and is less than or equal to 5% (0.02%≤covering rate≤5%). For example, the covering rate can be 0.05%, 0.5%, 1%, 1.5%, 2%, 3%, . . . , or 4.5%, and this disclosure is not limited thereto.

In another embodiment, if only the bottom surface B is configured with the stacked structure S (see FIG. 1C), the fourth heat conducting layer 17 is disposed on the part of the inner surface of the closed chamber 111 configured without the stacked structure S. This is, the fourth heat conducting layer 17 is disposed on the two side walls and the top surface T of the closed chamber 111. In addition, the feature of configuring the fourth heat conducting layer 17 can be used in combine with the features of other embodiments of the present disclosure, such as stepped or smoothly changed total thickness, the limitation of the range of the total thickness, or partially different materials.

The other technical features of the heat conducting structures 1a, 1b and 1c can refer to the same components of the heat conducting structure 1, so the detailed descriptions thereof will be omitted.

In addition, on the direction along the line X-X (the long-axis direction of the heat conducting unit 11) of the heat conducting structure 1, 1a, 1b or 1c, the above-mentioned stacked structure S (or S and S′) can be divided into at least two sections, which at least includes a first section and a second section. The materials of the first heat conducting layer 12 and the second heat conducting layer 14 in the first section are at least partially different from the materials of the first heat conducting layer 12 and the second heat conducting layer 14 in the second section. In other embodiments, the materials of the first heat conducting layer 12, the second heat conducting layer 14, and the third heat conducting layer 16 in the first section are at least partially different from the materials of the first heat conducting layer 12, the second heat conducting layer 14, and the third heat conducting layer 16 in the second section.

For example, as shown in FIG. 1C, the stacked structure S can be divided into a first section S1 disposed closest to the heat source end H and a second section S2 disposed closest to the cooling end C. The first section S1 is located next to the second section S2. The materials of the first heat conducting layer 12 and the second heat conducting layer 14 in the first section S1 are, for example, graphene and graphene, respectively, and the materials of the first heat conducting layer 12 and the second heat conducting layer 14 in the second section S2 are graphene and carbon nanotubes, respectively. As long as the first heat conducting layer 12 and the second heat conducting layer 14 in any of the two sections of the stacked structure S comprise different materials, the above-mentioned condition that the materials of the first heat conducting layer 12 and the second heat conducting layer 14 in the first section S1 are at least partially different from the materials of the first heat conducting layer 12 and the second heat conducting layer 14 in the second section S2 can be satisfied.

In addition, as shown in FIG. 3B, the stacked structures S and S′ can be respectively divided into first sections S1 and S1′ closest to the heat source end H and second sections S2 and S2′ closest to the cooling end C. The first sections S1 and S1′ are disposed next to the second sections S2 and S2′, respectively. The materials of the first heat conducting layer 12, the second heat conducting layer 14, and the third heat conducting layer 16 in the first sections S1 and S1′ are, for example, graphene, graphene, and carbon nanotubes, respectively, but the materials of the first heat conducting layer 12, the second heat conducting layer 14, and the third heat conducting layer 16 in the second sections S2 and ST are, for example, graphene, graphene, graphene, respectively. Alternatively, the materials of the first heat conducting layer 12, the second heat conducting layer 14, and the third heat conducting layer 16 in the second sections S2 and ST can be, for example, graphene, carbon nanotubes, and graphene, respectively. As long as the first heat conducting layer 12, the second heat conducting layer 14, and the third heat conducting layer 16 in any of the two sections of the stacked structure S or S′ comprise different materials, the above-mentioned condition that the materials of the first heat conducting layer 12, the second heat conducting layer 14, and the third heat conducting layer 16 in the first section S1 or ST are at least partially different from the materials of the first heat conducting layer 12, the second heat conducting layer 14, and the third heat conducting layer 16 in the second section S2 or ST can be satisfied. The above-mentioned materials are for illustrations only and are not to limit the scope of this disclosure.

Of course, in different embodiments, the stacked structure S or the stacked structures S and S′ can be divided into three or more sections, and the materials of the first heat conducting layers 12, the second heat conducting layers 14, and the third heat conducting layers 16 in at least two of the three or more sections are at least partially different from each other. In addition, the feature that the first heat conducting layers 12 and the second heat conducting layers 14 in at least two sections have different materials or the feature that first heat conducting layers 12, the second heat conducting layers 14, and the third heat conducting layers 16 in at least two sections have different materials can also be applicable to other embodiments of this disclosure, which have the feature of stepwise changed heat conducting structure of FIG. 1F or the feature of the smoothly changed heat conducting structure.

FIG. 4 is a schematic diagram showing a mobile device according to an embodiment of this disclosure. As shown in FIG. 4, the mobile device 2 is, for example, a mobile phone. The mobile device 2 comprises a heat source HS and a heat conducting structure 3. The heat conducting structure 3 is disposed inside the mobile device 2, and one end of the heat conducting structure 3 (the heat source end) is in contact with the heat source HS to conduct the heat energy generated by the heat source HS to the cooling end, thereby dissipating the heat to outside through the back cover (not shown) of the mobile device 2. The heat conducting structure 3 can be the above-mentioned heat conducting structure 1, 1a, 1b or 1c, or any of their modifications. The specific technical contents can be referred to the above embodiments, so the detailed descriptions thereof will be omitted. In addition, the heat source is, for example, the CPU of the mobile device 2. In some embodiments, the CPU of the mobile device 2 has a very high temperature, which may over 100° C., and the heat conducting structure of this disclosure can be used for heat conducting and dissipation of the mobile device 2. In other embodiments, the heat source can also be the memory chip (card), display chip (card), panel, or power component of the mobile device, or any of other components, units or assemblies that can generate high temperature.

To be noted, in an experimental example of the heat conducting structure of the present disclosure, the working fluid 15 is, for example, water, and the heat source temperature is, for example, 65° C. The materials of the first heat conducting layer 12 and the second heat conducting layer 14 are, for example, graphene, respectively, and the thickness thereof is, for example, between 0.6 nm and 1.5 nm. The material of the third heat conducting layer 16 is, for example, a carbon nanotube, and the thickness thereof is, for example, between 2 nm and 3 nm. The metal microstructure 13 is, for example, a copper mesh, and the thickness thereof is, for example, less than 80 μm. The comparison of the temperature differences between the heat conducting structure of this embodiment and the conventional vapor chamber (without the first heat conducting layer, the second heat conducting layer, and the third heat conducting layer) are shown in the following table:

| Structure on | | Graphene/copper | Graphene/copper |
|---|---|---|---|
| bottom surface | Copper | mesh/graphene/ | mesh/graphene/ |
| of first substrate | mesh | carbon nanotube | carbon nanotube |
| Structure on top | N/A | N/A | Graphene/copper |
| surface of second | | | mesh/graphene/ |
| substrate | | | carbon nanotube |
| Filled amount of | 0.1 g | 0.075 g | 0.07 g |
| working fluid | | | |
| Temperature | 2.7° C. | 1.5° C. | 1.2° C. |
| difference between | | | |
| heat source end | | | |
| and cooling end | | | |

As shown in the above table, if the conventional vapor chamber (only a copper mesh is disposed on the first substrate without configuring the first heat conducting layer, the second heat conducting layer and the third heat conducting layer) is used, the temperature difference between the heat source end and the cooling end can reach 2.7° C. In the case of using the heat conducting structure of one embodiment of the present disclosure, when the lower substrate is configured with a structure of carbon nanotube/graphene/copper mesh/graphene, the temperature difference between the heat source end and the cooling end is only 1.5° C. Moreover, when the lower substrate and the upper substrate are both configured with a structure of graphene/copper mesh/graphene/carbon nanotube, the temperature difference between the heat source end and the cooling end is only 1.2° C. The results of the above table prove that the heat conducting structure of the embodiment of the present disclosure does have a higher heat conducting efficiency and a better temperature uniform effect. These features of the disclosure can quickly dissipate the heat energy generated by the heat source, and can satisfy the heat dissipation requirements of the thin and light mobile device.

In a comparative example for long days of the present disclosure, two different heat conducting structures, which are referred to “a first heat conducting structure” and “a second heat conducting structure”, are selected. Herein, the “different heat conducting structures” means that the total thicknesses of the first heat conducting layer, the second heat conducting layer, and the third heat conducting layer are different, but the other conditions (e.g. materials and dimensions) are the same. The first heat conducting layer and the second heat conducting layer are, for example, graphene layers, the third heat conducting layer is made of, for example, carbon nanotubes, and the metal microstructure is made of, for example, a copper mesh (with uniform thickness).

In the first heat conducting structure, the total thicknesses of the first heat conducting layer, the second heat conducting layer and the third heat conducting layer in different sections are sequentially 500 nm, 300 nm, 50 nm and 5 nm in the direction from the heat source end to the cooling end. In the second heat conducting structure, the first heat conducting layer, the second heat conducting layer and the third heat conducting layer have a constant total thickness of 5 nm from the heat source end to the cooling end. Compared with the conventional vapor chamber (without the first heat conducting layer, the second heat conducting layer and the third heat conducting layer), the first heat conducting structure and the second heat conducting structure, which both comprise the first heat conducting layer, the second heat conducting layer and the third heat conducting layer, have a temperature difference between the heat source end and the cooling end lower than that of the conventional vapor chamber. This proves that the heat conducting structure of the present disclosure does have a higher heat conducting efficiency and a better temperature uniform effect. These features of the disclosure can quickly dissipate the heat energy generated by the heat source, and can satisfy the heat dissipation requirements of the thin and light mobile device.

In addition, after the first heat conducting structure and the second heat conducting structure both contact the heat source (e.g. 150° C.) and reach thermal balance, the temperature of the cooling end of the first heat conducting structure is 149.1° C. (the temperature difference between the heat source end and the cooling end is 0.9° C.), and the temperature of the cooling end of the second heat conducting structure is 147.6° C. (the temperature difference between the heat source end and the cooling end is 2.4° C.). After 30 days, the temperature of the cooling end of the first heat conducting structure is 148.6° C. (the temperature difference between the heat source end and the cooling end is 1.4° C.), and the temperature of the cooling end of the second heat conducting structure is 146.7° C. (the temperature difference between the heat source end and the cooling end is 3.3° C.). After 90 days, the temperature of the cooling end of the first heat conducting structure is 147.9° C. (the temperature difference between the heat source end and the cooling end is 2.1° C.), and the temperature of the cooling end of the second heat conducting structure is 145.2° C. (the temperature difference between the heat source end and the cooling end is 4.8° C.).

Two features can be seen from the above example. The first feature is: within the same time period, the temperature uniform effect of the first heat conducting structure is better than that of the second heat conducting structure. This can prove that the heat conducting structure has a better heat conducting efficiency when the total thickness of the first heat conducting layer, the second heat conducting layer and the third heat conducting layer adjacent to the heat source end is greater than the thickness of the first heat conducting layer, the second heat conducting layer and the third heat conducting layer away from the heat source end. The second feature is: the material and adhesion of graphene (the first heat conducting layer and the second heat conducting layer) may deteriorate as long time passes (e.g. 90 days), which may cause the increase of the temperature difference between the heat source end and the cooling end, thereby reducing the heat conducting efficiency. In addition, if adopting the first heat conducting structure, in which the total thickness of the first heat conducting layer, the second heat conducting layer and the third heat conducting layer adjacent to the heat source end is greater than the total thickness of the first heat conducting layer, the second heat conducting layer and the third heat conducting layer away from the heat source end, the degree of deterioration of the graphene is smaller, thereby delaying the deterioration of the material and adhesion thereof. Thus, the degree of deterioration of the heat conducting efficiency is also reduced. This example can prove the advantage of this disclosure.

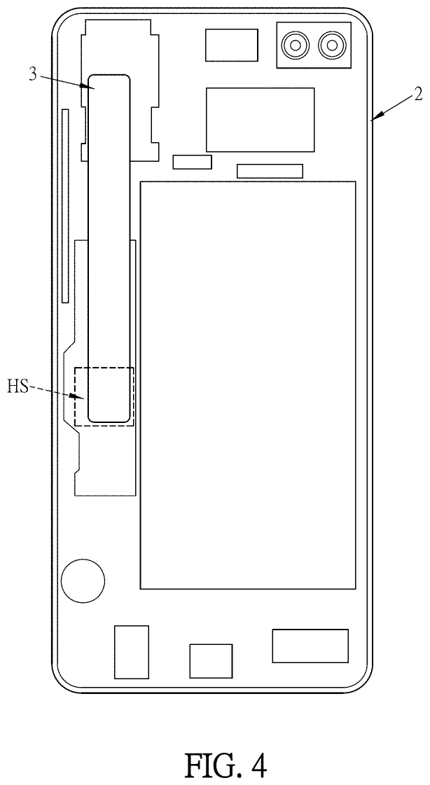

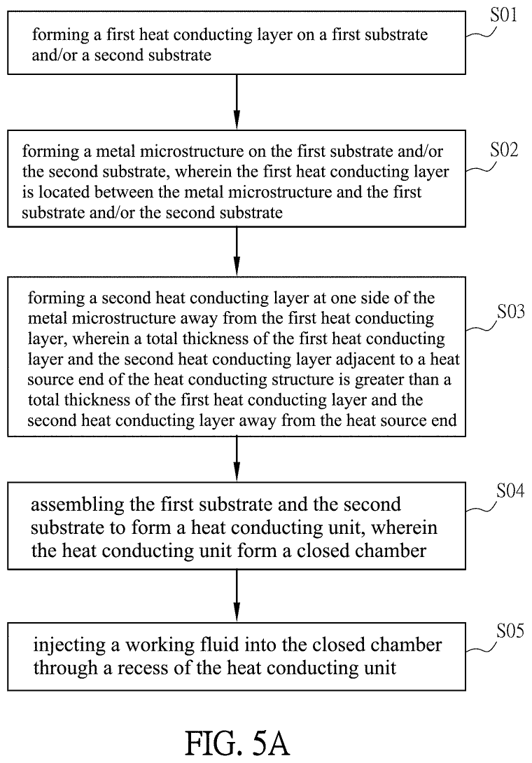

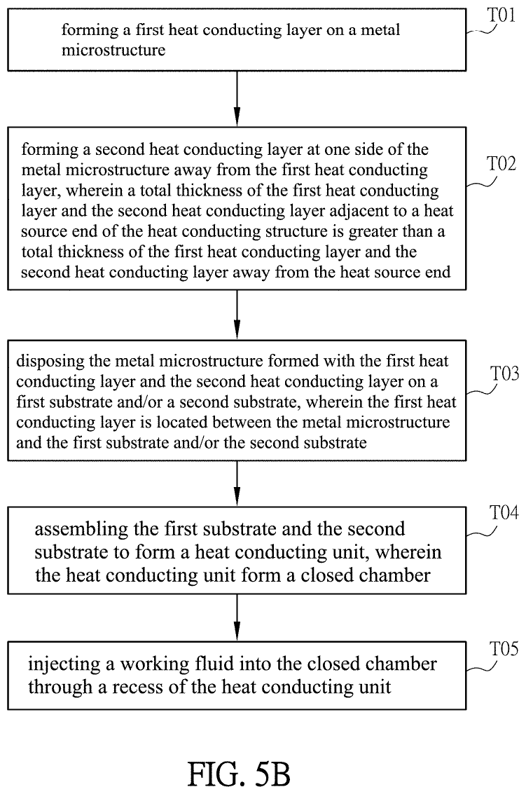

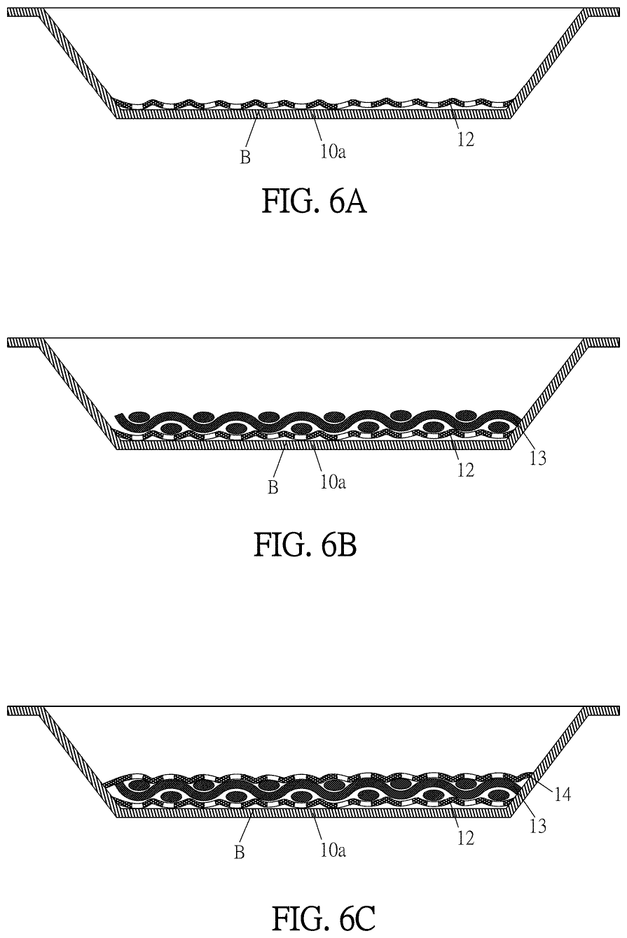

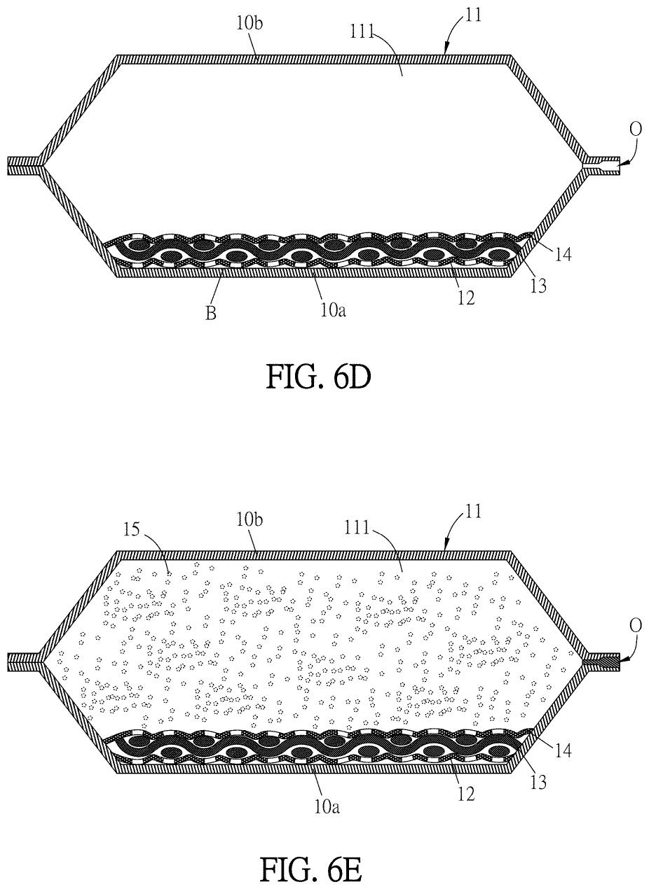

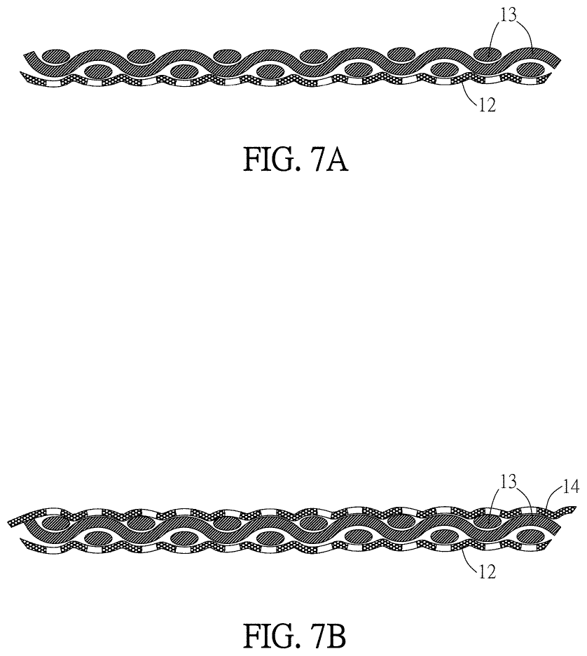

The manufacturing procedure of the heat conducting structure of this disclosure will be described hereinafter. FIGS. 5A and 5B are different flow charts of the manufacturing method of the heat conducting structure of this disclosure, FIGS. 6A to 6E are schematic diagrams showing the manufacturing procedure of the heat conducting structure according to an embodiment of this disclosure, and FIGS. 7A and 7B are schematic diagrams showing a part of another manufacturing procedure of the heat conducting structure according to an embodiment of this disclosure.

As shown in FIG. 5A, the manufacturing method of a heat conducting structure comprises steps S01 to S05. First, the step S01 is to form a first heat conducting layer 12 on a first substrate 10a and/or a second substrate 10b. As shown in FIG. 6A, the first heat conducting layer 12 (e.g. a graphene layer) is formed on the sunken bottom surface B of the first substrate 10a. In other embodiments, the first heat conducting layer 12 can be formed on a planar first substrate 10a, on a sunken first substrate 10a and a sunken second substrate 10b, or on a planar first substrate 10a and a planar second substrate 10b. This disclosure is not limited thereto. In some embodiments, the first heat conducting layer 12 can be formed on the first substrate 10a and/or the second substrate 10b by CVD (chemical vapor deposition), spraying, coating, adhesion, or any of other suitable methods. In some embodiments, each of the first substrate 10a and the second substrate 10b has a semi-cylindrical shape, so that they can be combined to form a heat pipe. The first heat conducting layer 12 is formed on the inner surface(s) of the first substrate 10a and/or the second substrate 10b. That is, the inner surface of the heat pipe is formed with the first heat conducting layer 12.

Next, the step S02 is to form a metal microstructure 13 on the first substrate 10a and/or the second substrate 10b, wherein the first heat conducting layer 12 is located between the metal microstructure 13 and the first substrate 10a and/or the second substrate 10b. As shown in FIG. 6B, the metal microstructure 13 (e.g. a copper mesh) is formed on the first substrate 10a, so that the first heat conducting layer 12 is located between the metal microstructure 13 and the first substrate 10a. In some embodiments, the metal microstructure 13 can be formed on the first substrate 10a and/or the second substrate 10b by heating process, heat sintering process, or any of other suitable methods, and the first heat conducting layer 12 can cover at least a part of the lower surface of metal microstructure 13. Thus, the first heat conducting layer 12 can be located between the metal microstructure 13 and the first substrate 10a and/or the second substrate 10b.

Afterwards, the step S03 is to form a second heat conducting layer 14 at one side of the metal microstructure 13 away from the first heat conducting layer 12, wherein a total thickness of the first heat conducting layer 12 and the second heat conducting layer 14 adjacent to a heat source end H of the heat conducting structure is greater than a total thickness of the first heat conducting layer 12 and the second heat conducting layer 14 away from the heat source end H. In some embodiments, the second heat conducting layer 14 (e.g. a graphene layer) can be formed on the metal microstructure 13 by, for example, chemical vapor deposition (CVD), electric welding, or adhesive bonding, or any of other suitable means to form the second heat conducting layer 14 on the metal microstructure 13, wherein the second heat conducting layer 14 covers at least a part of the upper surface of the metal microstructure 13 and the metal microstructure 13 is located between the second heat conducting layer 14 and the first heat conducting layer 12. In addition, in order to achieve that the total thickness of the first heat conducting layer 12 and the second heat conducting layer 14 adjacent to the heat source end H of the heat conducting structure is greater than the total thickness of the first heat conducting layer 12 and the second heat conducting layer 14 away from the heat source end H, for example, the means of mask or deposition time control can be used to deposit thicker first heat conducting layer 12 and second heat conducting layer 14 at the portion adjacent to the heat source end H, and to deposit thinner first heat conducting layer 12 and second heat conducting layer 14 at the portion away from the heat source end H, thereby achieving the feature of, for example, stepwise thickness variation.

Then, as shown in FIG. 6D, the step S04 is to assemble the first substrate 10a and the second substrate 10b to form a heat conducting unit 11, wherein the heat conducting unit 11 forms a closed chamber 111. In this embodiment, the first substrate 10a and the second substrate 10b can be assembled by welding or adhesion process to form the heat conducting unit 11 having the closed chamber 111. To be noted, in order to fill the working fluid 15 later, the side of the heat conducting unit 11 (e.g. on the second substrate 10b) must be configured with at least one recess O, so that the working fluid 15 can be injected through the recess O. In some embodiments, the recess O can be formed at, for example but not limited to, the connection portion at the side of the heat conducting unit 11.

Finally, the step S05 is to inject the working fluid 15 into the closed chamber 111 through the recess O of the heat conducting unit 11. In some embodiments, for example but not limited to, an injection needle is provided to insert into the recess O for injecting the working fluid 15 into the closed chamber 111. Then, the recess O is sealed so as to obtain the heat conducting structure 1 of FIG. 6E (similar to the structure of FIG. 1B).

In some embodiments, before the step S04 of assembling the first substrate 10a and the second substrate 10b, the manufacturing method of this disclosure further comprises a step of: forming a third heat conducting layer 16 at one side of the second heat conducting layer 14 away from the metal microstructure 13, wherein a total thickness of the first heat conducting layer 12, the second heat conducting layer 14, and the third heat conducting layer 16 adjacent to the heat source end H is greater than a total thickness of the first heat conducting layer 12, the second heat conducting layer 14, and the third heat conducting layer 16 away from the heat source end H. Afterwards, the above-mentioned steps S04 and S05 are performed. In some embodiments, the third heat conducting layer 16 can be formed by growing multi-wall carbon nanotube on the second heat conducting layer 14 by, for example, arc discharge method, laser vaporization method, or CVD. Preferably, the axial direction of the carbon nanotubes is perpendicular to the surface of the second heat conducting layer 14.

In some embodiments, before the step S04 of assembling the first substrate 10a and the second substrate 10b, the manufacturing method of this disclosure further comprises a step of: forming a fourth heat conducting layer 17 on a part of an inner surface of the closed chamber 111 configured without the stacked structure.

As shown in FIG. 5B, another manufacturing method of a heat conducting structure comprises steps T01 to T05. First, as shown in FIG. 7A, the step T01 is to form a first heat conducting layer 12 on a metal microstructure 13. In this embodiment, the first heat conducting layer 12 can be formed under the metal microstructure 13 by CVD, electric welding, or adhesive bonding, for covering at least a part of the lower surface of the metal microstructure 13. Then, as shown in FIG. 7B, the step T02 is to form a second heat conducting layer 14 at one side of the metal microstructure 13 away from the first heat conducting layer 12 for covering at least a part of the upper surface of the metal microstructure 13. Accordingly, the metal microstructure 13 can be located between the second heat conducting layer 14 and the first heat conducting layer 12, and a total thickness of the first heat conducting layer 12 and the second heat conducting layer 14 adjacent to a heat source end H of the heat conducting structure is greater than a total thickness of the first heat conducting layer 12 and the second heat conducting layer 14 away from the heat source end H. In some embodiments, the steps T01 and T02 can be simultaneously performed. That is, the second heat conducting layer 14 and the first heat conducting layer 12 can be formed on the upper surface and the lower surface of the metal microstructure 13, respectively, in a single manufacturing process.

Afterwards, the step T03 is to dispose the metal microstructure 13 formed with the first heat conducting layer 12 and the second heat conducting layer 14 on a first substrate 10a and/or a second substrate 10b, wherein the first heat conducting layer 12 is located between the metal microstructure 13 and the first substrate 10a and/or the second substrate 10b. Referring to FIG. 6C, the metal microstructure 13 formed with the first heat conducting layer 12 and the second heat conducting layer 14 is disposed on the sunken bottom surface B of the first substrate 10a, so that the first heat conducting layer 12 is located between the metal microstructure 13 and the first substrate 10a.

Then, as shown in FIG. 6D, the step T04 is to assemble the first substrate 10a and the second substrate 10b to form a heat conducting unit 11, wherein the heat conducting unit 11 forms a closed chamber 111. Finally, as shown in FIG. 6E, the step T05 is to inject a working fluid 15 into the closed chamber 111 through a recess O of the heat conducting unit 11. Then, the recess O is sealed to obtain the heat conducting structure 1.

Similarly, in some embodiments, before the step T04 of assembling the first substrate 10a and the second substrate 10b, the manufacturing method of this disclosure further comprises a step of: forming a third heat conducting layer 16 at one side of the second heat conducting layer 14 away from the metal microstructure 13, wherein a total thickness of the first heat conducting layer 12, the second heat conducting layer 14, and the third heat conducting layer 16 adjacent to the heat source end H is greater than a total thickness of the first heat conducting layer 12, the second heat conducting layer 14, and the third heat conducting layer 16 away from the heat source end H. Afterwards, the above-mentioned steps T04 and T05 are performed. In some embodiments, before the step T04 of assembling the first substrate 10a and the second substrate 10b, the manufacturing method of this disclosure further comprises a step of: forming a fourth heat conducting layer 17 on a part of an inner surface of the closed chamber 111 configured without the stacked structure.

The other technical features of the manufacturing methods of a heat conducting structure can refer to the above embodiments, so the detailed descriptions thereof will be omitted.

To be noted, in the structure and manufacturing process of the above embodiments of the present disclosure, the first heat conducting layer 12 and the second heat conducting layer 14 are specifically formed on two sides of the metal microstructure 13 in two different manufacturing processes, so that both sides of the metal microstructure 13 are deliberately covered by the first heat conducting layer 12 and the second heat conducting layer 14 respectively. The first heat conducting layer 12 and the second heat conducting layer 14 are formed by different manufacturing processes, but the materials thereof can be the same or different. This disclosure is different from the conventional structure obtained by forming the graphene layer in a process on the upper side of the copper microstructure. Moreover, since the both sides of the metal microstructure 13 of this disclosure is covered by the first heat conducting layer 12 and the second heat conducting layer 14, the hydrophilicity of the metal microstructure 13, the circulation efficiency of the working fluid 15, and the temperature uniform effect and the heat conducting effect of the heat conducting structure are superior to those of the structure fabricated by the conventional process.

To sum up, in the heat conducting structure, the manufacturing method thereof, and the mobile device of this disclosure, the first heat conducting layer and the second heat conducting layer are disposed at two sides of the metal microstructure inside the heat conducting structure. This configuration can increase the hydrophilicity of the metal microstructure so as to increase the reflux rate of the liquid working fluid at the metal microstructure, thereby accelerating the circulation efficiency of the working fluid, and improving the temperature uniform effect and heat conduction effect of the heat conducting structure. In addition, since the total thickness of the first heat conducting layer and the second heat conducting layer adjacent to the heat source end is greater than the total thickness of the first heat conducting layer and the second heat conducting layer away from the heat source end, the heat conducting structure can have a longer lifetime and better product reliability. As a result, the heat conducting structure of the present disclosure not only can satisfy the heat dissipation requirement of the thin and light mobile device, but also can rapidly dissipate the heat energy generated by the heat source to the outside, thereby having longer lifetime and better product reliability.

In some embodiments, the heat conducting structure of this disclosure further comprises a third heat conducting layer, which is disposed at one side of the second heat conducting layer away from the metal microstructure. The configuration of the third heat conducting layer can increase the heat conduction efficiency of the heat conducting structure, increase the coverage and hydrophilicity, and improve the protection of the metal microstructure so as to prevent corrosion or oxidation.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. A heat conducting structure, comprising:
a heat conducting unit forming a closed chamber, wherein the closed chamber has a bottom surface and a top surface, the bottom surface and the top surface are opposite to each other, two opposite ends of the heat conducting unit are functioned as a heat source end and a cooling end, respectively;
a first heat conducting layer disposed on the bottom surface and/or the top surface of the closed chamber;
a metal microstructure disposed on the first heat conducting layer, wherein the first heat conducting layer is located between the metal microstructure and the bottom surface and/or the top surface;
a second heat conducting layer disposed at one side of the metal microstructure away from the first heat conducting layer; and
a working fluid disposed in the closed chamber of the heat conducting unit;
wherein, a total thickness of the first heat conducting layer and the second heat conducting layer adjacent to the heat source end is greater than a total thickness of the first heat conducting layer and the second heat conducting layer away from the heat source end.

2. The heat conducting structure of claim 1, wherein the first heat conducting layer or the second conducting layer covers at least a part surface of the microstructure.

3. The heat conducting structure of claim 1, wherein the first heat conducting layer, the metal microstructure and the second heat conducting layer form a stacking structure, the stacking structure is divided into at least two sections along a long-axis direction, the at least two sections comprises a first section and a second section, and materials of the first heat conducting layer and the second heat conducting layer in the first section are at least partially different from material of the first heat conducting layer and the second heat conducting layer in the second section.

4. The heat conducting structure of claim 1, wherein the metal microstructure comprises a metal mesh, a metal powder, or a metal particle, or any combination thereof.

5. The heat conducting structure of claim 1, wherein a material of the first heat conducting layer or the second heat conducting layer comprises graphene, graphite, carbon nanotube, aluminum oxide, zinc oxide, titanium oxide, or boron nitride, or any combination thereof.

6. The heat conducting structure of claim 1, further comprising:
a third heat conducting layer disposed at one side of the second heat conducting layer away from the metal microstructure.

7. The heat conducting structure of claim 6, wherein a total thickness of the first heat conducting layer, the second heat conducting layer and the third heat conducting layer adjacent to the heat source end is greater than a total thickness of the first heat conducting layer, the second heat conducting layer and the third heat conducting layer away from the heat source end.

8. The heat conducting structure of claim 6, wherein the first heat conducting layer, the metal microstructure, the second heat conducting layer and the third heat conducting layer form a stacking structure, the stacking structure is divided into at least two sections along a long-axis direction, the at least two sections comprises a first section and a second section, and materials of the first heat conducting layer, the second heat conducting layer and the third heat conducting layer in the first section are at least partially different from material of the first heat conducting layer, the second heat conducting layer and the third heat conducting layer in the second section.

9. The heat conducting structure of claim 6, wherein the third heat conducting layer comprises a plurality of nanotubes, and axial directions of the nanotubes are perpendicular to a surface of the second heat conducting layer.

10. The heat conducting structure of claim 1, further comprising:
a fourth heat conducting layer disposed on a part of an inner surface of the closed chamber configured without the first heat conducting layer, the metal microstructure and the second heat conducting layer.

11. A manufacturing method of a heat conducting structure, comprising steps of:
forming a first heat conducting layer on a first substrate and/or a second substrate;
forming a metal microstructure on the first substrate and/or the second substrate, wherein the first heat conducting layer is located between the metal microstructure and the first substrate and/or the second substrate;
forming a second heat conducting layer at one side of the metal microstructure away from the first heat conducting layer, wherein a total thickness of the first heat conducting layer and the second heat conducting layer adjacent to a heat source end of the heat conducting structure is greater than a total thickness of the first heat conducting layer and the second heat conducting layer away from the heat source end;
assembling the first substrate and the second substrate to form a heat conducting unit, wherein the heat conducting unit forms a closed chamber; and
injecting a working fluid into the closed chamber through a recess of the heat conducting unit.

12. The manufacturing method of claim 11, before the step of assembling the first substrate and the second substrate, further comprising a step of:
forming a third heat conducting layer at one side of the second heat conducting layer away from the metal microstructure, wherein a total thickness of the first heat conducting layer, the second heat conducting layer and the third heat conducting layer adjacent to the heat source end is greater than a total thickness of the first heat conducting layer, the second heat conducting layer and the third heat conducting layer away from the heat source end.

13. The manufacturing method of claim 12, before the step of assembling the first substrate and the second substrate, further comprising a step of:
forming a fourth heat conducting layer on a part of an inner surface of the closed chamber configured without the first heat conducting layer, the metal microstructure, the second heat conducting layer, and the third heat conducting layer.

14. The manufacturing method of claim 11, before the step of assembling the first substrate and the second substrate, further comprising a step of:
forming a fourth heat conducting layer on a part of an inner surface of the closed chamber configured without the first heat conducting layer, the metal microstructure and the second heat conducting layer.

15. A manufacturing method of a heat conducting structure, comprising steps of:
forming a first heat conducting layer on a metal microstructure;
forming a second heat conducting layer at one side of the metal microstructure away from the first heat conducting layer, wherein a total thickness of the first heat conducting layer and the second heat conducting layer adjacent to a heat source end of the heat conducting structure is greater than a total thickness of the first heat conducting layer and the second heat conducting layer away from the heat source end;
disposing the metal microstructure formed with the first heat conducting layer and the second heat conducting layer on a first substrate and/or a second substrate, wherein the first heat conducting layer is located between the metal microstructure and the first substrate and/or the second substrate;
assembling the first substrate and the second substrate to form a heat conducting unit, wherein the heat conducting unit forms a closed chamber; and
injecting a working fluid into the closed chamber through a recess of the heat conducting unit.

16. The manufacturing method of claim 15, before the step of assembling the first substrate and the second substrate, further comprising a step of:
forming a third heat conducting layer at one side of the second heat conducting layer away from the metal microstructure, wherein a total thickness of the first heat conducting layer, the second heat conducting layer and the third heat conducting layer adjacent to the heat source end is greater than a total thickness of the first heat conducting layer, the second heat conducting layer and the third heat conducting layer away from the heat source end.

17. The manufacturing method of claim 16, before the step of assembling the first substrate and the second substrate, further comprising a step of:
forming a fourth heat conducting layer on a part of an inner surface of the closed chamber configured without the first heat conducting layer, the metal microstructure, the second heat conducting layer, and the third heat conducting layer.

18. The manufacturing method of claim 15, before the step of assembling the first substrate and the second substrate, further comprising a step of:
forming a fourth heat conducting layer on a part of an inner surface of the closed chamber configured without the first heat conducting layer, the metal microstructure and the second heat conducting layer.
